(19) United States
(12) Patent Application Publication
(10) Pub. No.: US 2025/0221087 A1
(43) Pub. Date: Jul. 3, 2025

(54) ULTRA-THIN TRANSMISSIVE CADMIUM ALLOY SOLAR CELL

(71) Applicant: Conti Innovation Center, LLC, Orlando, FL (US)

(72) Inventors: Kurt G. CONTI, New Providence, NJ (US); Cullin J. WIBLE, Austin, TX (US); Tim GESSERT, Conifer, CO (US)

(73) Assignee: Conti Innovation Center, LLC, Orlando, FL (US)

(21) Appl. No.: 18/400,407

(22) Filed: Dec. 29, 2023

(51) Int. Cl. H01L 31/0224; H01L 31/032; H01L 31/048

(52) U.S. Cl. CPC H10F 77/219; H10F 19/807; H10F 77/12; H10F 77/254

(57) ABSTRACT

An ultra-thin transmissive cadmium (Cd) alloy solar cell is provided. The ultra-thin transmissive cadmium (Cd) alloy solar cell includes a substrate section, a conductive section, a window section, and an absorber section. The absorber section includes a transmissive cadmium (Cd) alloy and a seven hundred (700) or less nanometer (nm) section thickness. The ultra-thin transmissive cadmium (Cd) alloy solar cell includes a percent (10%) transmissivity for portions of a first irradiance wavelength range between three hundred fifty (350) nanometers (nm) to approximately eight hundred twenty-five (825) nanometers (nm). The ultra-thin transmissive cadmium (Cd) alloy solar cell includes a sixty-five percent (65%) transmissivity for portions of a second irradiance wavelength range between to approximately eight hundred twenty-five (825) nanometers (nm) to one thousand two hundred (1200) nanometers (nm).

### FIELD OF INVENTION

The disclosure herein is related to an ultra-thin transmissive cadmium (Cd) alloy solar cell.

### BACKGROUND

Traditional photovoltaic solar cells, for example conventional crystalline silicon (c-Si) or cadmium telluride (CdTe) solar cells, are designed with metallic back contacts that are inherently opaque. Further, conventional bifacial solar cells have been developed where the opaque metal back contact has been replaced with a transparent conducting oxide (TCO). Accordingly, conventional bifacial solar cells absorb light from both sides. Yet, the conventional bifacial solar cells are still largely opaque as an absorber material therein is too thick to facilitate any sub-bandgap transparency.

In contrast these opaque solar cells, conventional transparent solar cells have been developed for window, display screen, skylight and similar applications. These conventional transparent solar cells include an absorber material that is somewhat transparent to the human eye. Note that the human eye is highly sensitive to visible light. Accordingly, conventional transparent solar cells focus on transparencies of less than ten percent (10%) of the visible light spectrum to accommodate how the human eye will perceive the visible light passing therethrough. By way of example, conventional transparent solar cells focus on uniform visible light spectrum transparency and color in the attempt to solve tinting or hueing in a window. Transparency fails to contemplate how the tinted or hued window affects the entire light spectrum (e.g., affects the ultraviolet and infrared light) and thus, transparency is not transmissivity. That is, conventional transparent solar cells fail to address a transmissivity of non-visible light spectrum entirely.

The primary goal of conventional transparent solar cells is to transmit visible light, with a secondary goal of generating some (minimal) electricity. Thus, existing research of the conventional transparent solar cells focuses on optimal transparency at the expense of electrical conversion. Further, research regarding the conventional transparent solar cells teaches that there is an inverse linear relationship between transparency and electrical output (e.g., electrical output decreases as transmissivity increases). As a result, no solar cell advancements or development have been made that can maintain electrical output while simultaneously increasing transmissivity.

Similarly, for conventional CdTe solar cells, CdTe research has been performed without regard to transmissivity because electrical output decreases as transmissivity increases. And, to the extent that conventional CdTe solar layers have contemplated transmissivity, conventional CdTe solar layers are indirectly developed to be transmissive as a result of producing intimately bonded cell architectures (e.g., traditional tandem cells including a CdTe and c-Si layers). Moreover, these intimate CdTe/c-Si layers cannot be separated (e.g., layers of the monolithic tandem cell architectures cannot be separated). Thus, the CdTe/c-Si layers of traditional tandem cells are unusable as independent devices and teach away from further transmissivity analysis or development.

Additionally, because light absorption decreases as thickness decreases, research for conventional CdTe solar layers has been performed without regard to thickness at or less than approximately six hundred (600) nanometers (nm). To the extent that a thickness of six hundred (600) nanometers (nm) to one thousand two hundred (1200) nanometers (nm) for conventional CdTe solar layers has been passingly discussed, there has been no substantive research, development, or publications with respect how conventional CdTe solar layers would work without being in a tandem configuration with c-Si layers, let alone at one thousand two hundred (1200) nanometers (nm) or less.

Moreover, as the thickness of the layers decreases, both the transmissivity and the electrical properties of the material change in a non-uniform manner. And even more importantly, as the thickness of the layers decreases, copper diffusion (which is a well-known complication in conventional CdTe solar cells) becomes more complex as the copper can more easily migrate through thinner layers. Note that all necessary dopants, deposition temperatures, deposition techniques, crystal structures, and other properties also change as the thickness of the layers decreases because these layers become more sensitive to all of these properties and process parameters. There has been no active research for any of these concerns to produce an optimally balanced highly transmissive and electrically functional CdTe solar cell.

There is a need for an alternative choice to conventional and traditional solar cells described herein. More particularly, there is a need for an ultra-thin transmissive cadmium (Cd) alloy solar cell that solves for and optimizes transmissivity through layer thickness and layer composition while maintaining commercially viable electrical output.

### SUMMARY

According to one or more embodiments, an ultra-thin transmissive cadmium (Cd) alloy solar cell is provided. The ultra-thin transmissive cadmium (Cd) alloy solar cell includes a substrate section, a conductive section, a window section, and an absorber section. The absorber section includes a transmissive cadmium (Cd) alloy and a seven hundred (700) or less nanometer (nm) section thickness. The ultra-thin transmissive cadmium (Cd) alloy solar cell includes at least ten percent (10%) transmissivity for one or more portions of a first irradiance wavelength range between three hundred fifty (350) nanometers (nm) to approximately eight hundred twenty-five (825) nanometers (nm). The ultra-thin transmissive cadmium (Cd) alloy solar cell includes a sixty-five percent (65%) transmissivity for one or more portions of a second irradiance wavelength range between to approximately eight hundred twenty-five (825) nanometers (nm) to one thousand two hundred (1200) nanometers (nm).

According to one or more embodiments, an ultra-thin transmissive cadmium (Cd) alloy solar cell is provided. The ultra-thin transmissive cadmium (Cd) alloy solar cell includes a substrate section, a conductive section, a window section, and an absorber section. The absorber section includes a transmissive cadmium (Cd) alloy. The ultra-thin transmissive cadmium (Cd) alloy solar cell includes a back contact section, a second conductive section, and a second substrate section. The ultra-thin transmissive cadmium (Cd) alloy solar cell for one or more portions of a first irradiance wavelength range between three hundred fifty (350) nanometers (nm) to approximately eight hundred twenty-five (825) nanometers (nm). The ultra-thin transmissive cadmium (Cd) alloy solar cell includes a sixty-five percent (65%) transmissivity for one or more portions of a second irradiance wavelength range between to approximately eight hundred twenty-five (825) nanometers (nm) to one thousand two hundred (1200) nanometers (nm). The ultra-thin transmissive cadmium (Cd) alloy solar cell includes a combined thickness of the window section, the absorber section, and the back contact section the comprises a seven hundred (700) or less nanometer (nm) thickness.

According to one or more embodiments, any of the ultra-thin transmissive cadmium (Cd) alloy solar cells described herein can be implemented in devices, apparatuses, and systems, and with respect to one or more methods.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1 depicts an ultra-thin transmissive cadmium (Cd) alloy solar cell according to one or more embodiments;

FIG. 2 depicts a graph according to one or more embodiments;

FIG. 3 depicts a system according to one or more embodiments; and

FIG. 4 depicts a graph according to one or more embodiments.

### DETAILED DESCRIPTION

The disclosure herein relates to ultra-thin transmissive cadmium (Cd) alloy solar cell. Light energy, generally, is irradiance across an entire light spectrum including, but not limited to, ultraviolet (UV) light, visible light, and infrared light. Transmissivity relates to an ability of a material or a section of a device to permit light energy (e.g., irradiance) that is not absorbed to transmit therethrough. Transparency relates to an ability of a material or a section of a device to permit visible light to pass therethrough. By way of examples, most windows are transparent to maximize the passing of the visible light. Further, tinting or hueing a window affects the visible light so that the window can be considered semi-transparent (e.g., not fully transparent). Transparency fails to contemplate how the tinted or hued window affects the entire light spectrum (e.g., how the tinted or hued window affects the UV light and the infrared light) and thus, transparency is not transmissivity.

According to one or more embodiments, the “ultra-thin” nature of ultra-thin transmissive cadmium (Cd) alloy solar cell is defined by a thickness of less than one thousand five hundred (1500) nanometers (nm) for a plurality of interior sections (e.g., a thickness at or less than one thousand (1000) nanometers (nm) for the plurality of interior sections). Further, the “transmissive” nature of ultra-thin transmissive cadmium (Cd) alloy solar cell 100 is defined by being highly transmissive for the entire light spectrum (e.g., includes designed transmissivities for different portions of the entire light spectrum). The “ultra-thin” and “transmissive” natures are interdependent because the plurality of interior sections of the ultra-thin transmissive cadmium (Cd) alloy solar cell 100 must be at an optimum thickness that can absorb irradiance to generate power and maintaining electrical output while transmitting non-absorbed irradiance.

According to one or more embodiments, the ultra-thin transmissive cadmium (Cd) alloy solar cell includes a substrate section, a conductive section, a window section, a absorber section. According to one or more embodiments, the ultra-thin transmissive cadmium (Cd) alloy solar cell can also include a back contact section, a second conductive section, and/or a second substrate section.

According to one or more embodiments, the substrate section (e.g., glass or plastic) can include a section thickness along a range from two (2) millimeters (mm) to four (4) millimeters (mm) (e.g., at approximately 3.2 mm). The conductive section (e.g., a front electrode including a tin oxide (SnO₂) layer, a fluorine-doped tin oxide (FTO) layer, an indium-doped tin oxide (ITO) layer, or other sufficiently transparent and conductive layers) can include a section thickness along a range from two hundred (200) nanometers (nm) to six hundred (600) nanometers (nm) (e.g., at approximately 400 nm). The window section can include a section thickness along a range from fifty (50) nanometers (nm) to one hundred fifty (150) nanometers (nm) (e.g., at approximately 100 nm). The absorber section (e.g., including a transmissive cadmium (Cd) alloy) can include a section thickness along a range from one hundred fifty (150) nanometers (nm) to seven hundred (700) nanometers (nm) (e.g., at six hundred fifty (650) or less nanometer (nm); at approximately 500 nm, 300 nm, or 200 nm). The back contact section can include a section thickness along a range from fifty (50) nanometers (nm) to one hundred fifty (150) nanometers (nm) (e.g., at approximately 100 nm of back contact. The second conductive section (e.g., a back electrode including SnO₂, FTO, ITO, or other transparent conductive oxides) can include a section thickness along a range from two hundred (200) nanometers (nm) to six hundred (600) nanometers (nm) (e.g., at approximately 400 nm). The second substrate section (e.g., glass or plastic) can include a section thickness along a range from one (1) millimeters (mm) to four (4) millimeters (mm) (e.g., at approximately 3.2 mm).

The ultra-thin transmissive cadmium (Cd) alloy solar cell receives light energy (from all directions, as well as angles) and converts a targeted amount of irradiance of the light energy to electricity, while unused irradiance of the light energy is passed therethrough. The ultra-thin transmissive cadmium (Cd) alloy solar cell includes at least ten percent (10%) transmissivity for a first irradiance wavelength range between three hundred fifty (350) nanometers (nm) to approximately eight hundred twenty-five (825) nanometers (nm). The ultra-thin transmissive cadmium (Cd) alloy solar cell includes at least sixty-five percent (65%) transmissivity for one or more portions of a second irradiance wavelength range between approximately eight hundred twenty-five (825) nanometers (nm) to one thousand two hundred (1200) nanometers (nm).

According to one or more technical effects, advantages, and benefits, the ultra-thin transmissive cadmium (Cd) alloy solar cell achieves an overall light energy power conversion efficiency (PCE) that is commercially viable. More particularly, the ultra-thin transmissive cadmium (Cd) alloy solar cell optimizes an architecture by designing for transmissivity and power conversion to optimize thickness to increase an overall light energy PCE and solve the compounding problems of conventional CdTe solar layers, as well as addressing to overcome material, diffusion, and quality problems. The technical effects, advantages, and benefits of the ultra-thin transmissive cadmium (Cd) alloy solar cell herein also include designing for transmissivity and thickness using new material combinations, new materials, and new configurations to enable the ultra-thin transmissive cadmium (Cd) alloy solar cell to work. The technical effects, advantages, and benefits of the ultra-thin transmissive cadmium (Cd) alloy solar cell herein also include enabling mechanically stacking with traditional photovoltaic solar cells to create a robust configuration that avoids the challenges of intimately bonded tandem cell architectures.

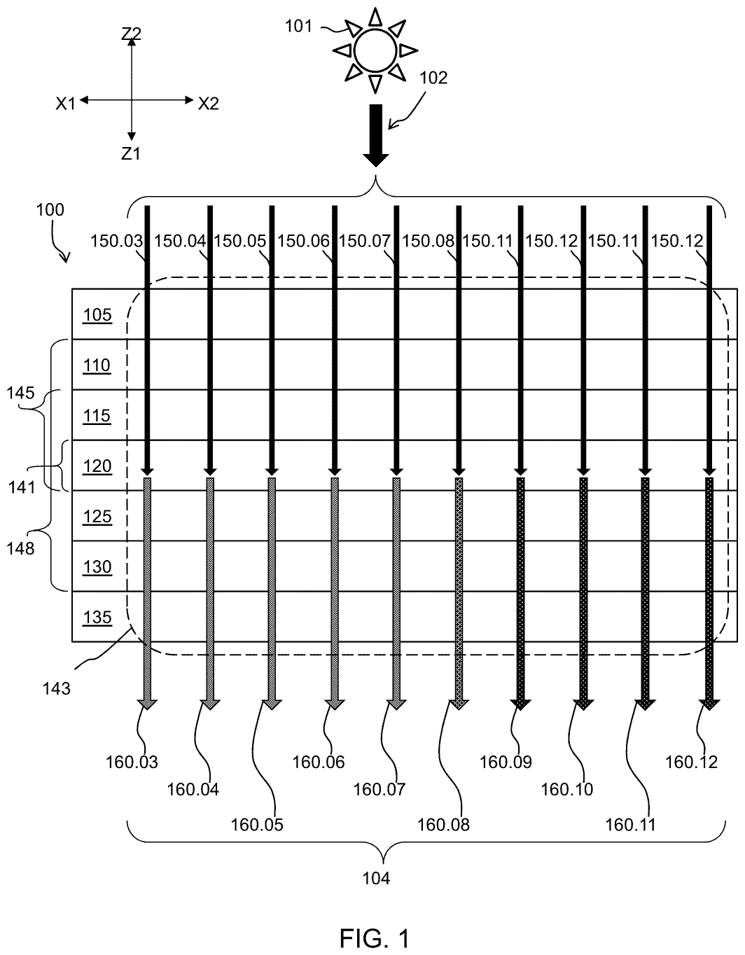

Turning to FIG. 1, an ultra-thin transmissive cadmium (Cd) alloy solar cell 100 is provided according to one or more embodiments.

The ultra-thin transmissive cadmium (Cd) alloy solar cell 100 of FIG. 1 is shown as a cross section oriented according to an X1-X2 axis and a Z1-Z2 axis. The X1-X2 axis is generally horizontal as oriented in the Figures, with the X1-X2 axis having a direction between left (X1) and right (X2). Accordingly, the X1 direction is opposite the X2 direction, reference to a left side or left facing surface of a component may be referred to as an X1 side or an X1 surface of the component, and reference to a right side or right facing surface of a component may be referred to as an X2 side or an X2 surface of the component. The Z1-Z2 axis is generally vertically as oriented in the Figures, with the axis having a direction between down (Z1) and up (Z2). Accordingly, the Z1 direction is opposite the Z2 direction, reference to a lower or bottom side or a downwardly facing surface of a component may be referred to as a Z1 side or a Z1 surface, and reference to a top or upper side or upwardly facing surface of a component may be referred to as a Z2 side or a Z2 surface. Other orientations (e.g., tilted or angled orientations) can be made in accordance with the X1-X2 axis and Z1-Z2 axis.

The ultra-thin transmissive cadmium (Cd) alloy solar cell 100 receives, from at least a sun 101 (e.g., from the Z2 direction and at a Z2 side of the ultra-thin transmissive cadmium (Cd) alloy solar cell 100), light energy or light 102. The light 102 can be considered incident light or natural light (though other sources are contemplated). The ultra-thin transmissive cadmium (Cd) alloy solar cell 100 absorbs and converts one or more portions of the light 102 into electricity or electrical power and transmits one or more remaining portions out of a Z1 side (e.g., a side opposite the sun 101) of ultra-thin transmissive cadmium (Cd) alloy solar cell 100 and in the Z1 direction, as transmitted light 104. One or more technical effect, benefits, and/or advantages includes that the ultra-thin transmissive cadmium (Cd) alloy solar cell 100 can be transparent, transmissive, semi-transparent, and/or semi-transmissive. The light 102 can range across a light spectrum including, but not limited to, ultraviolet (UV) light, visible light, and infrared light. The transmitted light 104 can also range across the light spectrum including, but at a lower intensity than the light 102 due to the absorption and conversion of the one or more portions of the light 102 by the ultra-thin transmissive cadmium (Cd) alloy solar cell 100.

The ultra-thin transmissive cadmium (Cd) alloy solar cell 100 includes a first substrate section 105, a first conductive section 110, a window section 115, and an absorber section 120. The ultra-thin transmissive cadmium (Cd) alloy solar cell 100 can further include a back contact section 125, a second conductive section 130, and/or a second substrate section 135. The sections of the ultra-thin transmissive cadmium (Cd) alloy solar cell 100 are manufactured in a vertical or Z direction. According to one or more embodiments, the ultra-thin transmissive cadmium (Cd) alloy solar cell 100 can be manufactured in a superstrate configuration in an order where the layers are deposited in decreasing deposition temperatures. For instance, to achieve transmissivity as described herein, deposition of the sections can be from section 135 to section 105 with decreasing deposition temperatures, so the deposition of any subsequent sections does not detrimentally affect one or more proceeding sections. According to one or more embodiments, the ultra-thin transmissive cadmium (Cd) alloy solar cell 100 can be manufactured in a substrate configuration in an order where the layers are deposited in decreasing deposition temperatures. For instance, to achieve transmissivity as described herein, deposition of the sections can be from section 105 to section 135 with decreasing deposition temperatures, so the deposition of any subsequent sections does not detrimentally affect one or more proceeding sections.

According to one or more embodiments, a Z2 side (e.g., a sun side) of the first substrate section 105 faces outward from the ultra-thin transmissive cadmium (Cd) alloy solar cell 100 and is exposed to the light 102, and a Z1 side (e.g., a side opposite the sun side) the first substrate section 105 faces inward. The Z1 side of the first substrate section 105 is adjacent to a Z2 side of the first conductive section 110. Adjacent in this context includes two sections being in contact and intimately bound. A Z1 side of the first conductive section 110 is adjacent to a Z2 side of the window section 115. A Z1 side of the window section 115 is adjacent to a Z2 side of the absorber section 120. A Z1 side of the absorber section 120 is adjacent to a Z2 side of the back contact section 125. A Z1 side of the absorber section 120 is adjacent to a Z2 side of the back contact section 125. A Z1 side of the back contact section 125 is adjacent to a Z2 side of the second conductive section 130. A Z1 side of the second conductive section 130 is adjacent to a Z2 side of the second substrate section 135. A Z2 side (e.g., a sun side) the second substrate section 135 faces inward (e.g., into to the ultra-thin transmissive cadmium (Cd) alloy solar cell 100), and a Z1 side (e.g., a side opposite the sun side) of the second substrate section 135 faces outward from the ultra-thin transmissive cadmium (Cd) alloy solar cell 100.

Generally, the Z2 side of the first substrate section 105 receives, from at least the sun 101, the light 102. The light 102 passes through, in the Z1 direction, the first substrate section 105, the first conductive section 110, and the window section 115 and into the absorber section 120. The absorber section 120 absorbs one or more portions of the light 102 received from the first conductive section 110 and can transmit the one or more remaining portions, as the transmitted light 104, towards the back contact section 125 (e.g., out of the Z1 side of the absorber section 120 in the Z1 direction). The transmitted light 104 passes through, in the Z1 direction, the back contact section 125, the second conductive section 130, and the second substrate section 135 and exits a Z1 side of the second substrate section 135.

The ultra-thin transmissive cadmium (Cd) alloy solar cell 100 can be representative an example of single cell of a module including a plurality of ultra-thin transmissive cadmium (Cd) alloy solar cells 100. The ultra-thin transmissive cadmium (Cd) alloy solar cell 100 can be representative a module of mechanically stacked solar modules within one or more apparatuses, devices, or systems. The ultra-thin transmissive cadmium (Cd) alloy solar cell 100 includes a five percent (5%) or greater power conversion efficiency (PCE) that adds to a total PCE of the mechanically stacked solar modules within one or more apparatuses, devices, or systems. According to one or more embodiments, the ultra-thin transmissive cadmium (Cd) alloy solar cell 100 can include a seven percent (7%) or greater power conversion efficiency. According to one or more embodiments, the ultra-thin transmissive cadmium (Cd) alloy solar cell 100 can include a ten percent (10%) or greater power conversion efficiency. For instance, as described herein, when the ultra-thin transmissive cadmium (Cd) alloy solar cell 100 is combined with the conventional crystalline silicon (c-Si) solar cell, the total PCE can be twenty-five percent (25%) or greater. Accordingly, embodiments of the ultra-thin transmissive cadmium (Cd) alloy solar cell 100 include apparatuses, systems, and/or methods at any possible technical detail level of integration.

The first substrate section 105 can be any glass or plastic that is transmissive. According to one or more embodiments, the transmissive quality of the first substrate section 105 includes a high transmissivity that transmits the entire light spectrum. According to one or more embodiments, the first substrate section 105 can include a section thickness along a range from two (2) millimeters (mm) to four (4) millimeters (mm) (e.g., at approximately 3.2 mm). The first substrate section 105 can be also be conductive.

An example of the first substrate section 105 can include, but is not limited to, a FTO glass substrate. The FTO glass substrate is a transmissive (e.g., which includes being transparent) conductive substrate, distinctively coated with FTO to provide electrical conductivity.

The first conductive section 110 can include a conductive glass, a conductive plastic, or other conductive material with a transmissive quality. The first conductive section 110 can include FTO, ITO, or sufficiently transparent and conductive layers oxide (e.g., a nanoparticle layer). According to one or more embodiments, the transmissive quality of the first conductive section 110 includes a high transmissivity that transmits the entire light spectrum. The first conductive section 110 can be referred to as a transmissive conductive front contact or a front electrode. The substrate section 110 can be an n-type transparent material, for example, an ITO-coated glass or FTO-coated glass. The first conductive section 110 can include a section thickness along a range from two hundred (200) nanometers (nm) to six hundred (600) nanometers (nm) (e.g., at approximately 400 nm).

The window section 115 can include a cadmium alloy and/or other transmissive absorber material. Examples of cadmium alloy include, but are not limited to, cadmium sulfide (CdS), cadmium selenide (CdSe), and cadmium telluride (CdTe), zinc telluride (ZnTe), and magnesium-doped zinc oxide (MZO). The window section 115 can include a one hundred (100) or less nanometer (nm) section thickness.

The window section 115 can be an n-type semiconductor or a p-type semiconductor, or combination thereof. The window section 115 can include a section thickness along a range from fifty (50) nanometers (nm) to one hundred fifty (150) nanometers (nm) (e.g., at approximately 100 nm).

The absorber section 120 includes a transmissive cadmium alloy and/or other transmissive absorber material. Examples of cadmium alloy include, but are not limited to, cadmium selenide (CdSe), cadmium telluride (CdTe), cadmium selenide telluride (CdSeTe), and cadmium zinc telluride (CdZnTe). The absorber section 120 (e.g., as well as other sections of the ultra-thin transmissive cadmium (Cd) alloy solar cell 100) can include, but is not limited to, cadmium, zinc, selenium, tin, oxygen, copper, nitrogen, aluminum, carbon, gold, platinum, palladium, sulfur, and other additives. The absorber section 120 can be an n-type semiconductor, an i-type semiconductor, a p-type semiconductor, or combination thereof. According to one or more embodiments and as further described herein, the absorber section 120 can have changing ratios n-type semiconductor, i-type semiconductor, and p-type semiconductor.

The absorber section 120 includes a thickness 141 (e.g., a section thickness). The thickness 141 can be a width of the absorber section 120 from the Z2 surface of the absorber section 120 to the Z1 surface of the absorber section 120. According to one or more embodiments, the thickness 141 can be at or less than seven hundred (700) nanometers (nm), for example, at or less than six hundred fifty (650) nanometer (nm) or at or less than five hundred (500) nanometers (nm). According to one or more embodiments, the thickness 141 can be along a range of one hundred (100) nanometers (nm) to seven hundred (700) nanometers (nm), for example, along a range from one hundred fifty (150) nanometers (nm) to six hundred fifty (650) nanometers (nm) (e.g., at approximately 500 nm, 300 nm, or 200 nm). The thickness 141 can be one hundred (100) nanometers (nm), one hundred fifty (150) nanometers (nm), two hundred (200) nanometers (nm), two hundred fifty (250) nanometers (nm), three hundred (300) nanometers (nm), three hundred fifty (350) nanometers (nm), four hundred (400) nanometers (nm), etc.

The thickness 141 can correspond to a transmissivity 143 of the ultra-thin transmissive cadmium (Cd) alloy solar cell 100. The transmissivity 143 is an ability of the ultra-thin transmissive cadmium (Cd) alloy solar cell 100 to permit one or more portions of the entire light spectrum (e.g., irradiance of ultraviolet (UV) light, visible light, and infrared light) that is not absorbed to transmit therethrough. The transmissivity 143 of the ultra-thin transmissive cadmium (Cd) alloy solar cell 100 can be designed for portions of the entire light spectrum irrespective of the other portions.

According to one or more embodiments, the transmissivity 143 of the ultra-thin transmissive cadmium (Cd) alloy solar cell 100 includes at least ten percent (10%) transmissivity for one or more portions of a first irradiance wavelength range between three hundred fifty (350) nanometers (nm) to approximately eight hundred twenty-five (825) nanometers (nm) (e.g., the transmissivity 143 can be fifteen percent (15%) or greater for the one or more portions of the first irradiance wavelength range). According to one or more embodiments, the transmissivity 143 of the ultra-thin transmissive cadmium (Cd) alloy solar cell 100 ultra-thin transmissive cadmium (Cd) alloy solar cell includes at least sixty-five percent (65%) transmissivity for one or more portions of a second irradiance wavelength range between to approximately eight hundred twenty-five (825) nanometers (nm) to one thousand two hundred (1200) nanometers (nm) (e.g., the transmissivity 143 can be seventy percent (70%) or greater for the one or more portions of the second irradiance wavelength range).

To design the transmissivity 143 for any particular irradiance wavelength range, the individual sections of the ultra-thin transmissive cadmium (Cd) alloy solar cell 100 can be configured at a thickness that provides a section transmissivity that contributes to or adds to the transmissivity 143. According to one or more embodiments, a section transmissivity of the absorber section 120 can include a ten percent (10%) or greater transmissivity for the one or more portions of the first irradiance wavelength range and/or can include a sixty-five percent (65%) or greater transmissivity for the one or more portions of the second irradiance wavelength range. Thus, a plurality of thicknesses of the sections, groups of sections (e.g., a combined thickness 145 or an internal thickness 148) and the ultra-thin transmissive cadmium (Cd) alloy solar cell 100 are contemplated by the ultra-thin transmissive cadmium (Cd) alloy solar cell 100 to achieve particular transmissive qualities.

According to one or more embodiments, the ultra-thin transmissive cadmium (Cd) alloy solar cell 100 can include the combined thickness 145. The combined thickness 145 can be an addition of section thicknesses for the window and absorber sections 115 and 125. The combined thickness 145 can be a width from the Z2 surface of the window section 115 to the Z1 surface of the absorber section 120. According to one or more embodiments, the combined thickness 145 can be at or less than one thousand (1000) nanometers (nm), for example, at or less than seven hundred fifty (750) nanometer (nm). The combined thickness 145 can also correspond to the transmissivity 143. By way of example, the combined thickness 145 can provide the at least ten percent (10%) transmissivity and the at least sixty-five percent (65%) transmissivity of the transmissivity 143, as described herein.

According to one or more embodiments, the ultra-thin transmissive cadmium (Cd) alloy solar cell 100 can include an internal thickness 148. The internal thickness 148 can be a width from the Z2 surface of the first conductive section 110 to the Z1 surface of the second conductive section 130. Configuring the total thickness 148, and the thicknesses of the section therein, defines the “ultra-thin” nature of the ultra-thin transmissive cadmium (Cd) alloy solar cell 100. According to one or more embodiments, the total thickness can be less than two thousand (2,000) nanometers (nm), for example, along a range of five hundred (500) nanometers (nm) to one thousand five hundred (1,500) nanometers (nm). Being less than two thousand (2,000) nanometers (nm) enables the transmissivity 143.

The back contact section 125 can include one or more conductors, which can be transmissive. The back contact section 125 can include one or more semiconductors, which can be transmissive. According to one or more embodiments, the back contact section 125 provides a tunnel junction or an ohmic contact on a bottom, back, rear or Z1 side of the absorber section 120. The back contact section 125 can have no bias on voltage or current changes and provide a stable and low resistance contact for p-type cadmium telluride (CdTe) or other cadmium alloys. For instance, the back contact section 125 can include one or more gold (Au), aluminum (Al), platinum (Pt), zinc telluride (ZnTe) (e.g., doped with Copper (Cu) or other material), zinc telluride (ZnTe) based alloy (e.g., doped with Copper (Cu) or other material), or other material/alloy at a thickness that maintains transmissivity. The back contact section 125 can include a section thickness along a range from fifty (50) nanometers (nm) to one hundred fifty (150) nanometers (nm) (e.g., at approximately 100 nm of back contact. Note that conductive sections of conventional and traditional solar cells are generally opaque; thus, the ultra-thin transmissive cadmium (Cd) alloy solar cell 100 either replaces these conductive sections with transmissive conductors and/or semiconductors or reduces a thickness thereof to a transmissive dimension (i.e., five (5) to two hundred (200) nanometers or nm for gold (Au)).

The second conductive section 130 (e.g., a back electrode) can include material that provides an electrical path for electricity to leave the ultra-thin transmissive cadmium (Cd) alloy solar cell 100. The material of the second conductive section 130 can include a conductive glass, a conductive plastic, or other conductive material with a transmissive quality (e.g., including FTO, ITO, or other transparent conductive oxide, as well as or in the alternative one or more of ultra-thin carbon (C), ultra-thin aluminum (Al), ultra-thin gold (Au), and graphene). The second conductive section 125 can include a section thickness along a range from two hundred (200) nanometers (nm) to six hundred (600) nanometers (nm) (e.g., at approximately 400 nm).

The second substrate section 135 can be any glass or plastic that is transmissive. According to one or more embodiments, the transmissive quality of the second substrate section 135 includes a high transmissivity that transmits the entire light spectrum. The second substrate section 135 can be also be conductive. According to one or more embodiments, the second substrate section 135 can include a section thickness along a range from one (1) millimeters (mm) to four (4) millimeters (mm) (e.g., at approximately 3.2 mm). An example of the second substrate section 135 can include, but is not limited to, a FTO-coated glass of ITO-coted glass.

As described herein, the ultra-thin transmissive cadmium (Cd) alloy solar cell 100 receives, from at least the sun 101, the light 102. As shown in FIG. 1, the light 102 can includes at least one or more portions 150.03, 150.04, 150.05, 150.06, 150.07, 150.08, 150.09, 150.10, 150.11, and 150.12. Generally, the ultra-thin transmissive cadmium (Cd) alloy solar cell 100 absorbs and converts one or more portions 150.03, 150.04, 150.05, 150.06, 150.07, 150.08, 150.09, 150.10, 150.11, and 150.12 into electricity or electrical power and transmits one or more remaining portions 160.03, 160.04, 160.05, 160.06, 160.07, 160.08, 160.09, 160.10, 160.11, and 160.12 out of the Z1 side (e.g., a side opposite the sun 101) of ultra-thin transmissive cadmium (Cd) alloy solar cell 100 and in the Z1 direction, as the transmitted light 104.

The one or more portions 150.03, 150.04, 150.05, 150.06, 150.07, 150.08, 150.09, 150.10, 150.11, and 150.12 can respectively represent the light 102 at approximately three hundred (300), four hundred (500), five hundred (500), six hundred (600), seven hundred (700), eight hundred (800), nine hundred (900), one thousand (1,000), one thousand one hundred (1,100), and one thousand two hundred (1,200) nanometers (nm) wavelengths. In this regard, the one or more portions 150.03, 150.04, 150.05, 150.06, 150.07, 150.08, 150.09, 150.10, 150.11, and 150.12 are depicted as solid arrows to represent that the light 102 at that wavelength has a full amount of energy. Note that these wavelength values illustrate the light 102 as presented by the sun 101 across the full light spectrum (including between the values) and not at just those exact values.

Similarly, the one or more remaining portions 160.03, 160.04, 160.05, 160.06, 160.07, 160.08, 160.09, 160.10, 160.11, and 160.12 can respectively represent the light 104 at approximately three hundred (300), four hundred (500), five hundred (500), six hundred (600), seven hundred (700), eight hundred (800), nine hundred (900), one thousand (1,000), one thousand one hundred (1,100), and one thousand two hundred (1,200) nanometers (nm) wavelengths. Note that these wavelength values illustrate the light 104 as affected by the ultra-thin transmissive cadmium (Cd) alloy solar cell 100 across the full light spectrum (including between the values) and not at just those exact values. In this regard, the one or more remaining portions 160.03, 160.04, 160.05, 160.06, 160.07, 160.08, 160.09, 160.10, 160.11, and 160.12 are depicted with arrows that include degrees of shading to illustrate a spectral response of the absorber section 120 to the one or more portions 150.03, 150.04, 150.05, 150.06, 150.07, 150.08, 150.09, 150.10, 150.11, and 150.12.

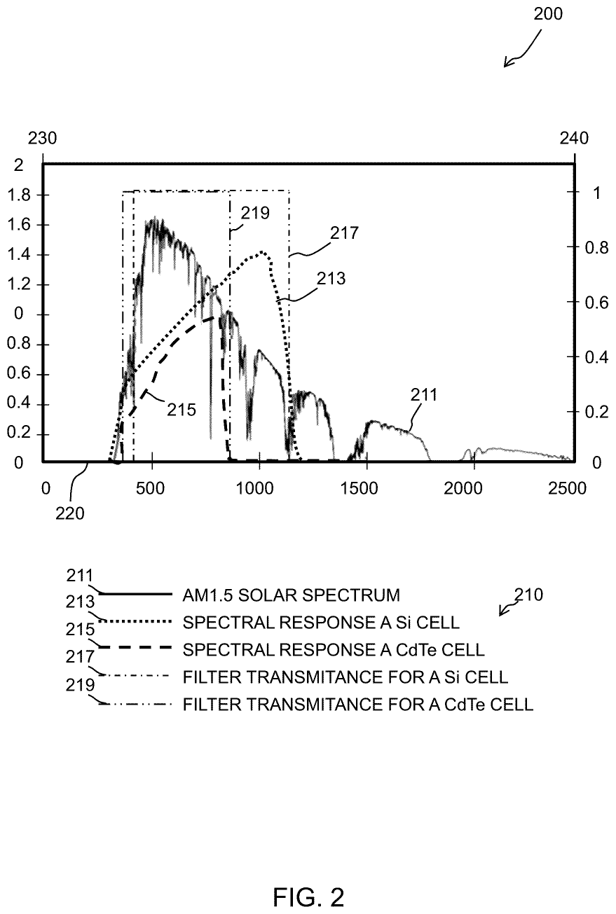

Turning to FIG. 2, a graph 200 and a key 210 identifying lines within the graph 200 is depicted according to one or more embodiments. The graph 200 depicts spectral response and transmittance qualities of cadmium telluride (CdTe), which is an example transmissive cadmium (Cd) alloy of the ultra-thin transmissive cadmium (Cd) alloy solar cell 100, and silicon (Si). The key 210 includes a line 211 representing a AM1.5 solar spectrum, a line 213 representing a spectral response of a silicon (Si) cell, a line 215 representing a spectral response of a cadmium telluride (CdTe) cell, a line 217 representing a filter transmittance of a silicon (Si) cell, and a line 219 representing a filter transmittance of a cadmium telluride (CdTe) cell. The graph 200 includes an x-axis 220 showing a scale for wavelengths in nanometers (nm), a left y-axis 230 showing a spectral intensity in W/m²/nm, and a right y-axis 240 showing spectral response in A/W, transmittance [−].

The approximate absorption range for the cadmium telluride (CdTe) cell is 400 nanometers (nm) to 825 nanometers (nm), which can be respective to a first irradiance wavelength range. The approximate absorption for the Si cell is 450 nanometers (nm) to 1200 nanometers (nm). A second irradiance wavelength range can be the 825 nanometers (nm) to 1200 nanometers (nm). For example, the ultra-thin transmissive cadmium (Cd) alloy solar cell 100 absorbs portions of an irradiance wavelength range of the light 102 (as represented by the line 211) in the 400 to 825 nanometer wavelength range (e.g., at least the one or more portions 160.03, 160.04, 160.05, 160.06, and 160.07 of FIG. 1) in accordance with the spectral response (as represented by line 215). Further, the ultra-thin transmissive cadmium (Cd) alloy solar cell 100 transits unabsorbed light energy of the 400 to 825 nanometer wavelength range (e.g., at least the one or more remaining portions 150.03, 150.04, 150.05, 150.06, and 150.07 that are less shaded), which can be represented by the difference between the line 211 and the line 213. Furthermore, the ultra-thin transmissive cadmium (Cd) alloy solar cell 100 transits light energy outside of that range with some energy loss (e.g., at least the one or more remaining portions 150.09, 150.10, 150.11, and 150.12 that are more shaded). Note that there can be variability on the border between the first and second wavelength ranges, as shown by the intermediate shading of the remaining portion 150.08.

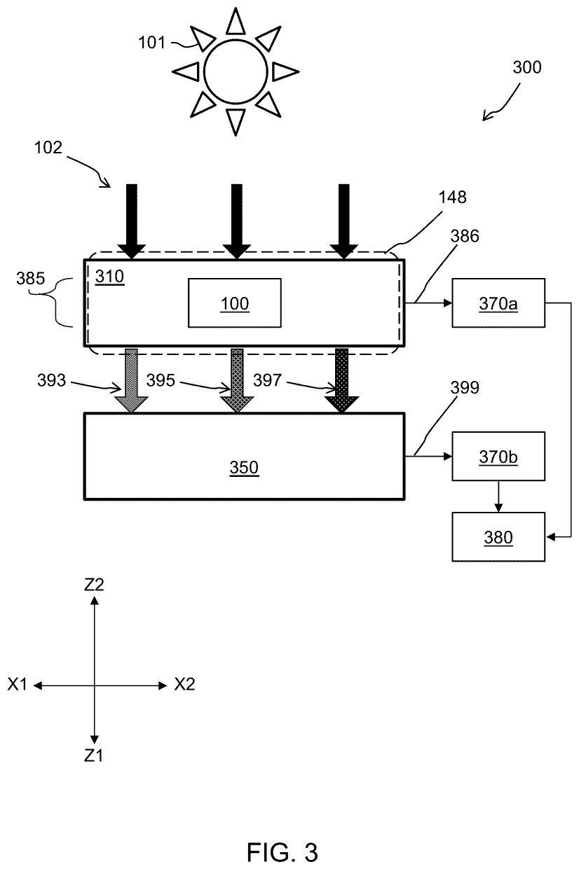

FIG. 3 depicts a system 300 according to one or more embodiments. The system 300 illustrates an example of how the disclosure herein balances thickness versus transmissivity in contemplation of a crystalline silicon (c-Si) performance. The system 300 can be an example of a modular system.

According to one or more embodiments, the system 300 includes at least two modules (representative of cells or modules including a plurality of cells). As shown in FIG. 3, the system 300 includes a module 310 and a module 350. The module 310 can include one or more of the ultra-thin transmissive cadmium (Cd) alloy solar cell 100 of FIG. 1. The module 350 can include one or more crystalline silicon (c-Si) cells (though other sources are contemplated).

According to one or more embodiments, the module 310 can include one or more of the ultra-thin transmissive cadmium (Cd) alloy solar cells 100 that include at least the first substrate section 105, the first conductive section 110, the window section 115, and the absorber section 120. According to one or more embodiments, the module 310 can include one or more of the ultra-thin transmissive cadmium (Cd) alloy solar cells 100 that further include the back contact section 125 and the second conductive section 130. For example, the module 310 can be fixed (e.g., by an adhesive or other mechanism) to a Z2 side of the module 350 so a Z2 face of the module 350 acts as Z1 substrate of the module 310. According to one or more embodiments, the module 310 includes an “ultra-thin” nature as defined by a thickness 385 of less than one thousand five hundred (1500) nanometers (nm) for a plurality of interior sections (e.g., the thickness 385 is at or less than one thousand (1000) nanometers (nm) for the first conductive section 110, the window section 115, the absorber section 120, the back contact section 125, and the second conductive section 130 of FIG. 1).

According to one or more embodiments, the module 310 can include one or more of the ultra-thin transmissive cadmium (Cd) alloy solar cells 100 that further include the second substrate section 135. For example, the module 310 can be fixed (e.g., by an adhesive or other mechanism) to a Z2 side of the module 350 so a Z2 face of the module 350 is in contact with the Z1 substrate (e.g., the second substrate section 135) of the module 310.

The system 300 includes one or more boxes 370 and a bus 380. The one or more boxes 370 can be electrical combiner boxes that have corresponding to strings to individually support and connect to one of the modules 310 and 350 of the system 300. For example, the one or more boxes 370 can be hard wired electrical connections that provide outlets, connections, or other interfaces for receiving electricity the one or more modules 310 and 350. As shown in FIG. 3, each module 310 and 350 individually and separately connects to a corresponding box 370a and 370b, respectively, so that each module 310 and 350 can individually and separately provide independently generated electricity. The bus 380 can be representative of additional electrical components, for example, a bus connector and box, that forward the electricity to a power grid, a battery, or other destination.

The system 300 is designed to enable the electrically separate modules 310 and 350 to independently work for electrical aggregation (e.g., which further enables a broader electrical component scope to achieve power aggregation). In operation, the system 300 receives, from at least the sun 101, the light 102 (though other sources are contemplated). The module 310 converts the light 102 received on a Z2 side (or a sun or first side) into electricity 386 and transmit unconverted portions 393, 395, and 397 of the light energy to the module 350. The module 350 convert at least part of the unconverted portions 393, 395, and 397 of the light energy into electricity 399. By way of example, the module 310 can absorb the light 102 at the first irradiance wavelength range and transits unabsorbed light energy 393 of the first irradiance wavelength range (e.g., shown with less shading). Further, the module 310 can transits the light 102 at the second irradiance wavelength range as the unabsorbed light energy 397 with some energy loss (e.g., shown with more shading). Note that there can be absorption and transmission variability on the border between the first and second irradiance wavelength ranges, as shown by the intermediate shading of the light 395.

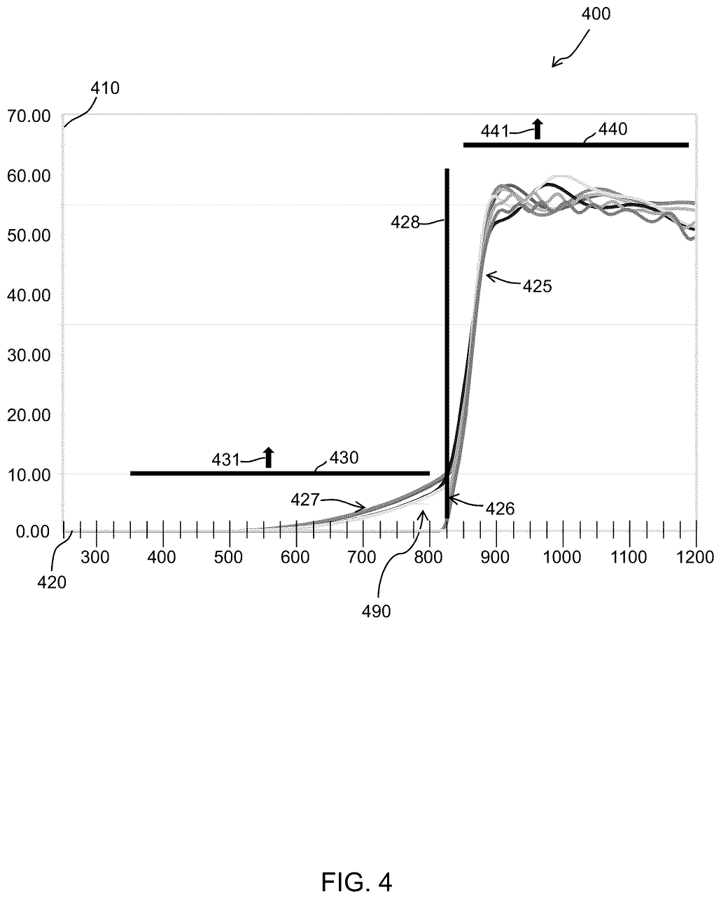

FIG. 4 depicts a graph 400 according to one or more embodiments. The graph 200 includes a y-axis 410 showing a percentage of transmissivity and an x-axis 420 showing a scale for wavelengths in nanometers (nm), within which a plurality of test result plots 425 of existing cadmium telluride (CdTe) cells manufactured by National Renewable Energy Laboratory (NREL) are provided. The plot grouping 426 shows a performance of existing NREL cadmium telluride (CdTe) cells at a thickness of three point three (3.3) microns (um), which are opaque at eight hundred twenty-five (825) nanometers and less (e.g., to the left of line 428). The plot grouping 427 shows a performance of existing NREL cadmium telluride (CdTe) cells at a thickness of six hundred fifty (650) nanometers (nm), which are opaque at five hundred (500) nanometers (nm) irradiance wavelength and less, and which averages less than five percent (5%) transmissivity for a five hundred (500) nanometers (nm) to eight hundred twenty-five (825) nanometers (nm) irradiance wavelength range (e.g., to the left of line 428). Additionally, the plurality of test result plots 425 shows a performance of existing NREL cadmium telluride (CdTe) cells at less than sixty percent 60% transmissivity for greater than eight hundred twenty-five (825) nanometers (nm) irradiance wavelengths (e.g., to the right of line 428).

The ultra-thin transmissive cadmium (Cd) alloy solar cell described herein is designed to be ultra-thin (e.g., include a seven hundred (700) or less nanometer (nm) section thickness for an absorber section), with an average transmissivity of five percent (5%) or greater for the first irradiance wavelength range between three hundred fifty (350) nanometers (nm) to approximately eight hundred twenty-five (825) nanometers (nm). According to one or more embodiment, any portion of the light within the first irradiance wavelength range can be at least five percent (5%) transmissivity. According to one or more embodiment, any portion of the light within the first irradiance wavelength range can be at least seven percent (7%) transmissivity. According to one or more embodiment, any portion of the light within the first irradiance wavelength range can be at least ten percent (10%) transmissivity. In this regard, as shown in FIG. 4, a performance of ultra-thin transmissive cadmium (Cd) alloy solar cell described herein (e.g., including a seven hundred (700) or less nanometer (nm) section thickness for an absorber section) has one or more portions of light within the first irradiance wavelength range at ten percent (10%) transmissivity (represented by line 430) or greater (represented by line 431).

The ultra-thin transmissive cadmium (Cd) alloy solar cell described herein is designed to be ultra-thin (e.g., include a seven hundred (700) or less nanometer (nm) section thickness for an absorber section), with an average transmissivity of sixty percent (60%) or greater for the second irradiance wavelength range between approximately eight hundred twenty-five (825) nanometers (nm) to one thousand two hundred (1200) nanometers (nm). According to one or more embodiment, any portion of the light within the second irradiance wavelength range can be at least sixty percent (60%) transmissivity. According to one or more embodiment, any portion of the light within the second irradiance wavelength range can be at least sixty-five percent (65%) transmissivity. In this regard, as shown in FIG. 4, a performance of ultra-thin transmissive cadmium (Cd) alloy solar cell described herein (e.g., including a seven hundred (700) or less nanometer (nm) section thickness for an absorber section) has one or more portions of light within the second irradiance wavelength range at sixty-five percent (65%) transmissivity (represented by line 440) or greater (represented by line 441).

Note that existing NREL cadmium telluride (CdTe) cells provide only a minor change in transmissivity percentage, as depicted by the region 490, due to the change in thickness between three point three (3.3) microns (um) and six hundred fifty (650) nanometers (nm). As a technical effect, benefit, and advantage, the ultra-thin transmissive cadmium (Cd) alloy solar cell described herein contemplates, designs for, and includes thickness to achieve particular transmissive qualities and maintains performance (e.g., power generation) in view of being ultra-thin. In this regard, conventional CdTe solar layers (i.e., existing NREL cadmium telluride (CdTe) cells) are opaque to the left of line 428 (so their thicknesses do not enable transmissivity) and are further attached to metal contacts that are opaque (that eliminate a need to design for transmissivity), or are intimately bonded in a tandem cell (without regard to transmissivity at wavelengths to the right of line 428).

According to one or more embodiments, an ultra-thin transmissive cadmium (Cd) alloy solar cell is provided. The ultra-thin transmissive cadmium (Cd) alloy solar cell includes a substrate section, a conductive section, a window section, and an absorber section. The absorber section includes a transmissive cadmium (Cd) alloy and a seven hundred (700) or less nanometer (nm) section thickness. The ultra-thin transmissive cadmium (Cd) alloy solar cell includes at least ten percent (10%) transmissivity for one or more portions of a first irradiance wavelength range between three hundred fifty (350) nanometers (nm) to approximately eight hundred twenty-five (825) nanometers (nm). The ultra-thin transmissive cadmium (Cd) alloy solar cell includes at least sixty-five percent (65%) transmissivity for one or more portions of a second irradiance wavelength range between to approximately eight hundred twenty-five (825) nanometers (nm) to one thousand two hundred (1200) nanometers (nm).

According to one or more embodiments or any of the ultra-thin transmissive cadmium (Cd) alloy solar cell embodiments herein, the window section can include a one hundred (100) or less nanometer (nm) section thickness.

According to one or more embodiments or any of the ultra-thin transmissive cadmium (Cd) alloy solar cell embodiments herein, a combined thickness of the window and absorber sections can provide the at least ten percent (10%) transmissivity for one or more portions of the first irradiance wavelength range and the at least sixty-five percent (65%) transmissivity for the one or more portions of the second irradiance wavelength range for the ultra-thin transmissive cadmium (Cd) alloy solar cell.

According to one or more embodiments or any of the ultra-thin transmissive cadmium (Cd) alloy solar cell embodiments herein, the window section can include cadmium selenide (CdSe).

According to one or more embodiments or any of the ultra-thin transmissive cadmium (Cd) alloy solar cell embodiments herein, the seven hundred (700) or less nanometer (nm) section thickness of the absorber section can include a five hundred (500) or less nanometer (nm) section thickness.

According to one or more embodiments or any of the ultra-thin transmissive cadmium (Cd) alloy solar cell embodiments herein, the seven hundred (700) or less nanometer (nm) section thickness of the absorber section can include a thickness along a range of one hundred (100) nanometers (nm) to six hundred (600) nanometers (nm).

According to one or more embodiments or any of the ultra-thin transmissive cadmium (Cd) alloy solar cell embodiments herein, the transmissive cadmium (Cd) alloy of the absorber section can include at least one of cadmium selenide (CdSe), cadmium telluride (CdTe), cadmium selenide telluride (CdSeTe), and cadmium zinc telluride (CdZnTe).

According to one or more embodiments or any of the ultra-thin transmissive cadmium (Cd) alloy solar cell embodiments herein, the ultra-thin transmissive cadmium (Cd) alloy solar cell can include a fifteen percent (15%) or greater transmissivity for the one or more portions of the first irradiance wavelength range.

According to one or more embodiments or any of the ultra-thin transmissive cadmium (Cd) alloy solar cell embodiments herein, the ultra-thin transmissive cadmium (Cd) alloy solar cell can include a seventy percent (70%) or greater transmissivity for the one or more portions of the second irradiance wavelength range.

According to one or more embodiments or any of the ultra-thin transmissive cadmium (Cd) alloy solar cell embodiments herein, the substrate section can include a glass or a plastic.

According to one or more embodiments or any of the ultra-thin transmissive cadmium (Cd) alloy solar cell embodiments herein, the conductive section can include an indium-doped tin oxide or a fluorine-doped tin oxide.

According to one or more embodiments or any of the ultra-thin transmissive cadmium (Cd) alloy solar cell embodiments herein, the ultra-thin transmissive cadmium (Cd) alloy solar cell can include a five percent (5%) or greater power conversion efficiency.

According to one or more embodiments or any of the ultra-thin transmissive cadmium (Cd) alloy solar cell embodiments herein, the ultra-thin transmissive cadmium (Cd) alloy solar cell comprises a ten percent (10%) or greater power conversion efficiency.

According to one or more embodiments or any of the ultra-thin transmissive cadmium (Cd) alloy solar cell embodiments herein, the ultra-thin transmissive cadmium (Cd) alloy solar cell can includes a second conductive section, a back contact section comprising one or more transmissive conductors or semiconductors, and a second substrate section comprising a glass or a plastic.

According to one or more embodiments or any of the ultra-thin transmissive cadmium (Cd) alloy solar cell embodiments herein, the one or more transmissive conductors or semiconductors can include at least one metal, metal alloy, or semiconductor material at a thickness that provides a transmissivity of non-absorbed irradiance exiting the absorber section.

According to one or more embodiments, an ultra-thin transmissive cadmium (Cd) alloy solar cell is provided. The ultra-thin transmissive cadmium (Cd) alloy solar cell includes a substrate section, a conductive section, a window section, and an absorber section. The absorber section includes a transmissive cadmium (Cd) alloy. The ultra-thin transmissive cadmium (Cd) alloy solar cell includes a back contact section, a second conductive section, and a second substrate section. The ultra-thin transmissive cadmium (Cd) alloy solar cell includes at least ten percent (10%) transmissivity for one or more portions of a first irradiance wavelength range between three hundred fifty (350) nanometers (nm) to approximately eight hundred twenty-five (825) nanometers (nm). The ultra-thin transmissive cadmium (Cd) alloy solar cell includes at least sixty-five percent (65%) transmissivity for one or more portions of a second irradiance wavelength range between to approximately eight hundred twenty-five (825) nanometers (nm) to one thousand two hundred (1200) nanometers (nm). The ultra-thin transmissive cadmium (Cd) alloy solar cell includes a combined thickness of the window section, the absorber section, and the back contact section the comprises a seven hundred (700) or less nanometer (nm) thickness.

According to one or more embodiments or any of the ultra-thin transmissive cadmium (Cd) alloy solar cell embodiments herein, the window section can include a one hundred (100) or less nanometer (nm) section thickness.

According to one or more embodiments or any of the ultra-thin transmissive cadmium (Cd) alloy solar cell embodiments herein, the absorber section can include a five hundred (500) or less nanometer (nm) section thickness.

According to one or more embodiments or any of the ultra-thin transmissive cadmium (Cd) alloy solar cell embodiments herein, the second substrate section can include a glass or a plastic.

According to one or more embodiments or any of the ultra-thin transmissive cadmium (Cd) alloy solar cell embodiments herein, the second conductive section can include an indium-doped tin oxide or a fluorine-doped tin oxide.

According to one or more embodiments or any of the ultra-thin transmissive cadmium (Cd) alloy solar cell embodiments herein, the ultra-thin transmissive cadmium (Cd) alloy solar cell can include a five percent (5%) or greater power conversion efficiency.

According to one or more embodiments or any of the ultra-thin transmissive cadmium (Cd) alloy solar cell embodiments herein, the ultra-thin transmissive cadmium (Cd) alloy solar cell comprises a ten percent (10%) or greater power conversion efficiency.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

Although features and elements are described above in particular combinations, one of ordinary skill in the art will appreciate that each feature or element can be used alone or in any combination with the other features and elements. The drawings, graphs, flowcharts, and diagrams in the Figures illustrate the architecture, functionality, and operation of possible implementations of devices, apparatuses, and systems, and with respect to one or more methods, according to various embodiments. In this regard, each block in the flowchart or block diagrams may represent a module, a segment, a layer, a device, or portion of thereof. In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved.

The descriptions of the various embodiments herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An ultra-thin transmissive cadmium (Cd) alloy solar cell comprising:
a substrate section;
a conductive section;
a window section;
an absorber section comprising a transmissive cadmium (Cd) alloy;
a back contact section comprising one or more transmissive semiconductors; and
a second non-metal conductive section; and
a second substrate section comprising fluorine-doped tin oxide coated glass,
wherein the ultra-thin transmissive cadmium (Cd) alloy solar cell comprises:
at least ten percent (10%) transmissivity for one or more portions of a first irradiance wavelength range between three hundred fifty (350) nanometers (nm) to approximately eight hundred twenty-five (825) nanometers (nm), and
at least sixty-five percent (65%) transmissivity for one or more portions of a second irradiance wavelength range between to approximately eight hundred twenty-five (825) nanometers (nm) to one thousand two hundred (1200) nanometers (nm),
wherein a combined thickness of the window section, the absorber section, and the back contact section comprises a seven hundred (700) nanometer (nm) or less thickness.

2. The ultra-thin transmissive cadmium (Cd) alloy solar cell of claim 1, wherein the window section comprises a one hundred (100) nanometer (nm) or less section thickness.

3. (canceled)

4. The ultra-thin transmissive cadmium (Cd) alloy solar cell of claim 1, wherein the window section comprises cadmium selenide (CdSe).

5. The ultra-thin transmissive cadmium (Cd) alloy solar cell of claim 1, wherein the seven hundred (700) nanometer (nm) or less thickness comprises a five hundred (500) nanometer (nm) or less section thickness of the absorber section.

6. The ultra-thin transmissive cadmium (Cd) alloy solar cell of claim 1, wherein the seven hundred (700) or nanometer (nm) or less thickness comprises a section thickness of the absorber section along a range of one hundred (100) nanometers (nm) to six hundred (600) nanometers (nm).

7. The ultra-thin transmissive cadmium (Cd) alloy solar cell of claim 1, wherein the transmissive cadmium (Cd) alloy of the absorber section comprises at least one of cadmium selenide (CdSe), cadmium telluride (CdTe), cadmium selenide telluride (CdSeTe), and cadmium zinc telluride (CdZnTe).

8. The ultra-thin transmissive cadmium (Cd) alloy solar cell of claim 1, wherein the ultra-thin transmissive cadmium (Cd) alloy solar cell comprises a fifteen percent (15%) or greater transmissivity for the one or more portions of the first irradiance wavelength range.

9. The ultra-thin transmissive cadmium (Cd) alloy solar cell of claim 1, wherein the ultra-thin transmissive cadmium (Cd) alloy solar cell comprises a seventy percent (70%) or greater transmissivity for the one or more portions of the second irradiance wavelength range.

10. The ultra-thin transmissive cadmium (Cd) alloy solar cell of claim 1, wherein the conductive section comprises an indium-doped tin oxide or a fluorine-doped tin oxide.

11. The ultra-thin transmissive cadmium (Cd) alloy solar cell of claim 1, wherein the ultra-thin transmissive cadmium (Cd) alloy solar cell comprises a five percent (5%) or greater power conversion efficiency.

12. The ultra-thin transmissive cadmium (Cd) alloy solar cell of claim 1, wherein the ultra-thin transmissive cadmium (Cd) alloy solar cell comprises a ten percent (10%) or greater power conversion efficiency.

13. (canceled)

14. (canceled)

15. An ultra-thin transmissive cadmium (Cd) alloy solar cell comprising:
a first transmissive substrate section;
a first transmissive conductive section;
a window section comprising a one hundred (100) nanometer (nm) or less section thickness;
an absorber section comprising a transmissive cadmium (Cd) alloy and a five hundred (500) nanometer (nm) or less section thickness;
a back contact section comprising one or more transmissive semiconductors;
a second conductive section comprising transmissive non-metal material; and
a second substrate section comprising transmissive material,
wherein the ultra-thin transmissive cadmium (Cd) alloy solar cell comprises:
at least ten percent (10%) transmissivity for one or more portions of a first irradiance wavelength range between three hundred fifty (350) nanometers (nm) to approximately eight hundred twenty-five (825) nanometers (nm), and
at least sixty-five percent (65%) transmissivity for one or more portions of a second irradiance wavelength range between to approximately eight hundred twenty-five (825) nanometers (nm) to one thousand two hundred (1200) nanometers (nm), and
wherein a combined thickness of the window section, the absorber section, and the back contact section comprises a seven hundred (700) nanometer (nm) or less thickness.

16. (canceled)

17. (canceled)

18. The ultra-thin transmissive cadmium (Cd) alloy solar cell of claim 15, wherein the transmissive material comprises a fluorine-doped tin oxide coated glass.

19. The ultra-thin transmissive cadmium (Cd) alloy solar cell of claim 15,
wherein the ultra-thin transmissive cadmium (Cd) alloy solar cell comprises a five percent (5%) or greater power conversion efficiency.

20. The ultra-thin transmissive cadmium (Cd) alloy solar cell of claim 15, wherein the ultra-thin transmissive cadmium (Cd) alloy solar cell comprises a ten percent (10%) or greater power conversion efficiency.

21. The ultra-thin transmissive cadmium (Cd) alloy solar cell of claim 1, wherein the one or more transmissive semiconductors comprise a zinc telluride (ZnTe) based alloy doped with copper (Cu).

22. (canceled)

23. (canceled)

24. The ultra-thin transmissive cadmium (Cd) alloy solar cell of claim 1, wherein the back contact section comprises a one hundred fifty (150) nanometer (nm) or less section thickness.

25. The ultra-thin transmissive cadmium (Cd) alloy solar cell of claim 1, wherein the second non-metal conductive section transmits a non-absorbed irradiance exiting the absorber section.

26. The ultra-thin transmissive cadmium (Cd) alloy solar cell of claim 1, wherein the second non-metal conductive section comprises a six hundred (600) nanometer (nm) or less section thickness.

27. The ultra-thin transmissive cadmium (Cd) alloy solar cell of claim 1, wherein the combined thickness comprises a value along a range of a five hundred fifty (550) nanometers (nm) to one hundred fifty (150) nanometers (nm).

28. An ultra-thin transmissive cadmium (Cd) alloy solar cell comprising:
a first transmissive substrate section;
a first transmissive conductive section;
a transmissive window section;
a transmissive absorber section comprising a transmissive cadmium (Cd) alloy;
a transmissive back contact section comprising at least transmissive semiconductors and comprising a section thickness along a range of ten (10) nanometers (nm) to two hundred (200) nanometers (nm);
a transmissive non-metal second conductive section comprising indium-doped tin oxide coated glass;
a transmissive second substrate section comprising glass,
wherein a combined thickness of the transmissive window section, the transmissive absorber section, and the transmissive back contact section comprises a value along a range of a five hundred (500) nanometers (nm) to two hundred fifty (250) nanometers (nm),
wherein materials of each section of the ultra-thin transmissive cadmium (Cd) alloy solar cell comprises at least fifteen percent (15%) transmissivity for one or more portions of a first irradiance wavelength range between three hundred fifty (350) nanometers (nm) to approximately eight hundred twenty-five (825) nanometers (nm), and
wherein the ultra-thin transmissive cadmium (Cd) alloy solar cell comprises at least seventy percent (70%) transmissivity for one or more portions of a second irradiance wavelength range between to approximately eight hundred twenty-five (825) nanometers (nm) to one thousand two hundred (1200) nanometers (nm).
